(19) United States
(12) Patent Application Publication
(10) Pub. No.: US 2026/0051834 A1
(43) Pub. Date: Feb. 19, 2026

(54) METHOD TO IDENTIFY ROTOR SLOT HARMONICS IN A MOTOR CURRENT SPECTRUM

(71) Applicant: Eaton Intelligent Power Limited, Dublin 4 (IE)

(72) Inventors: Gurmeet Singh, Pune (IN); Priyabrata Shaw, Balasore (IN); Prashanth A. Telkar, Bangalore (IN)

(21) Appl. No.: 18/808,539

(22) Filed: Aug. 19, 2024

(51) Int. Cl. H02P 23/14; G01R 19/10; G01R 19/165; H02P 25/062; H02P 27/04; H02P 29/024

(52) U.S. Cl. CPC H02P 23/14; G01R 19/10; G01R 19/16547; H02P 25/062; H02P 27/047; H02P 29/024

(57) ABSTRACT

A method to identify rotor slot harmonics (RSH) in a motor current spectrum of an AC induction motor includes receiving current data from the motor operated at two different load values, obtaining a motor current frequency spectrum comprising a first motor current spectrum corresponding to a first load value and a second motor current spectrum corresponding to a second load value, detecting a number of peak current values for a frequency range of the motor current frequency spectrum, and comparing the detected number of peak current values for the frequency range from the first motor current spectrum to the second motor current spectrum. Pairs of consecutive peaks are determined from the detected number of peak current values for each of first load value and second load value and compared. When the comparison is above a threshold value, the pair of consecutive peak current values are identified as RSH.

### BACKGROUND

An induction motor is an alternating current (AC) motor in which the electric current in the rotor that produces torque is obtained by electromagnetic induction from the magnetic field of the stator winding. In an induction motor, rotor slots (openings where conductors are placed) can lead to harmonic components in the stator current waveform. The harmonics are generated due to an interaction between the stator and rotor magnetic fields and are related to the geometry of the rotor slots. Rotor slot harmonic components can be used to estimate the induction motor speed as well as diagnosing faults within the induction motor.

Rotor slot harmonics (RSH) are generally seen in a motor current spectrum. However, in the current spectrum, the detection of the rotor slot harmonics can be difficult due to the presence of other frequency components unrelated to RSH on the motor current spectrum. Additionally, RSH may not be present in the motor current spectrum. RSH typically only exist under certain conditions that depend on the number of poles and rotor bars. Therefore, a more accurate method to identify the rotor slot harmonics in a motor current spectrum is desired.

### BRIEF SUMMARY

A method to identify rotor slot harmonics in a motor current spectrum of an induction motor is provided. Through processes described herein, the rotor slot harmonics of an induction motor can be identified and used to determine the rotor speed of the induction motor as well as diagnose faults in the induction motor.

A computer-implemented method to identify rotor slot harmonics in a motor current spectrum of an AC induction motor includes: receiving current data from the AC induction motor operated at two different load values; obtaining a motor current frequency spectrum comprising a first motor current spectrum corresponding to a first load value and a second motor current spectrum corresponding to a second load value; detecting a number of peak current values for a frequency range of the motor current frequency spectrum; and comparing the detected number of peak current values for the frequency range from the first motor current spectrum to the second motor current spectrum. Comparing the detected number of peak current values for the frequency range from the first motor current spectrum to the second motor current spectrum includes determining a pair of consecutive peak current values from the detected number of peak current values, the pair of consecutive peak current values include a first peak current value for the first load value and a second peak current value for the second load value; calculating a difference between the first peak current value and the second peak current value; comparing the difference to a threshold value; and in response to the difference being greater than zero and less than the threshold value, identifying the pair of consecutive peak current values as rotor slot harmonics.

A method to determine a fault of an induction motor system includes: driving a load by an induction motor; measuring a current of the load driven by the induction motor; estimating a rotor speed of the induction motor; performing a first comparison by comparing the measured current of the load to a baseline load current; performing a second comparison by comparing the estimated rotor speed of the induction motor to a baseline rotor speed wherein the baseline rotor speed is estimated using identified rotor slot harmonics; and determining a fault of the induction motor system based on the first comparison and the second comparison.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an operating environment for an induction motor system according to one embodiment.

FIG. 2 illustrates an operating environment for an induction motor system according to another embodiment.

FIG. 3 illustrates a flowchart of a method to identify rotor slot harmonics in a motor current spectrum of an induction motor.

FIG. 4 illustrates a graph of a motor current frequency spectrum of a 10 HP induction motor operated with a DOL soft starter.

FIG. 5 illustrates a motor current spectrum of 40 HP induction motor operated by a DOL soft starter.

FIG. 6 illustrates a method depicting a process to determine induction motor system faults using identified RSH.

FIG. 7 illustrates a schematic diagram illustrating components of a computing device.

### DETAILED DESCRIPTION

A method to identify rotor slot harmonics in a motor current spectrum of an induction motor is provided. Through processes described herein, the rotor slot harmonics of an induction motor can be identified and used to determine the rotor speed of the induction motor as well as diagnose faults in the motor. The presented method can be performed to identify the presence of RSH in the current spectrum of an induction motor fed by a fixed frequency, e.g., direct online (DOL) soft starter or a variable frequency drive. Additionally, the presented method can be used for any configuration of motor windings, including star configurations and delta configurations.

Currently, rotor speed estimation is accomplished using different techniques and methods. For example, the rotor speed can be obtained directly using a tachometer coupled to the motor. However, using a tachometer requires access to the motor which can sometimes be difficult, e.g., it resides in a closed housing or resides at a remote location. Additionally, approximation methods such as a straight-line approximation method can be used to estimate rotor speed are simplistic, but not very accurate. There are also complex techniques that are more accurate but are not useful under all conditions. An accurate, simplistic method utilizing the motor current spectrum analysis to identify rotor slot harmonics of an induction motor is presented. The identified RSH can then be used to accurately estimate the speed of the motor or diagnose faults in the motor.

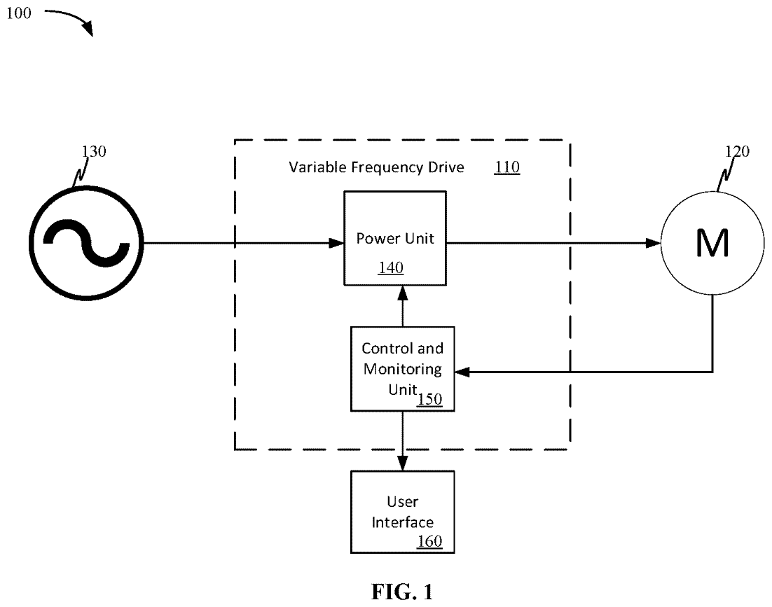

FIG. 1 illustrates an operating environment for an induction motor system according to one embodiment. Referring to FIG. 1, operating environment 100 includes a motor drive 110 and an induction motor 120. In the illustrated embodiment, the motor drive 110 is a variable frequency drive (VFD). VFD 110 is coupled to a grid 130 that provides the VFD 110 with a three-phase AC power input. VFD 110 includes power unit 140 and a control and monitoring unit 150. VFD 110 receives the three phase AC input which is fed to power unit 140. Power unit 140 converts the AC power input to a DC power, inverts and conditions the DC power to a controlled AC power for transmission to AC induction motor 120. VFD 110 also includes a control and monitoring unit 150 that receives current data from the induction motor 120. In one embodiment, as illustrated in FIG. 1, the control and monitoring unit 150 is integrated into VFD 110. In other embodiments, control and monitoring unit 150 can be included in an edge device coupled to the VFD or reside in a cloud environment. User interface 160 can be included for communication between the control and monitoring unit 150 and a user.

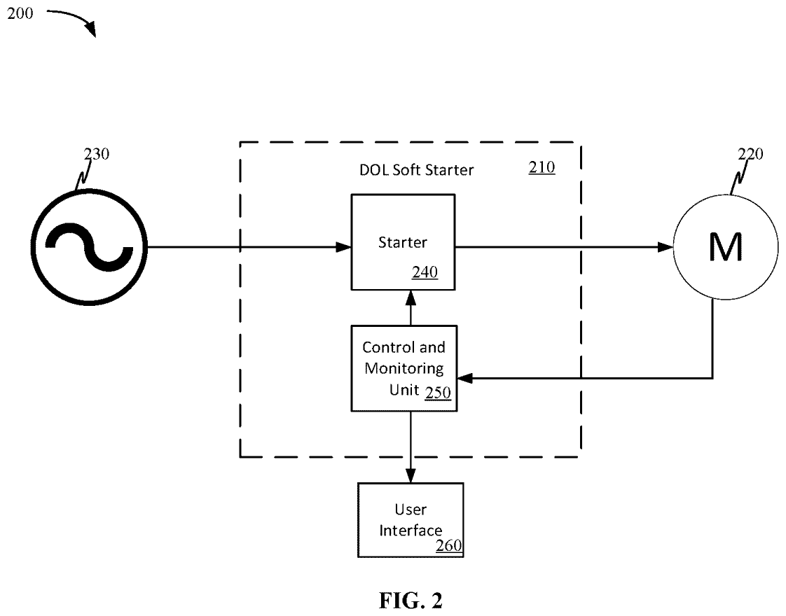

FIG. 2 illustrates an operating environment for implementing a control and monitoring unit of an induction motor according to another embodiment. Referring to FIG. 2, operating environment 200 includes motor drive 210, e.g., DOL soft starter, and induction motor 220. The DOL soft starter 210 is coupled to the grid 230. DOL soft starter 210 includes starter 240 and control and monitoring unit 250. Starter 240 transmits power between the grid 230 and the induction motor 220. Similar to the VFD example described previously, DOL soft starter 210 also includes a control and monitoring unit 250 that receives current data from the induction motor 220. In one embodiment, as illustrated in FIG. 2, the control and monitoring unit 250 is integrated into soft starter 210. In other embodiments, control and monitoring unit 250 can be included in an edge device coupled to the DOL soft starter 210 or reside in a cloud environment. User interface 260 can be included for communication between the control and monitoring unit 250 and a user.

Control and monitoring unit 150, 250 receives motor current data in the form of current signals from the induction motor. Current data can be obtained from current sensors positioned to receive appropriate current signals for motor current analysis. The received motor current data can be used to obtain a motor current spectrum by performing a FFT (Fast Fourier Transform) or other frequency-domain signal processing technique on the received motor current data. In graphical form, the motor current spectrum illustrates the individual spectral components of the current signal providing frequency information about the current signal.

Identifying the rotor slot harmonics of an induction motor mathematically is possible, however, it can be challenging to obtain the required values needed for the calculations. In order to calculate the rotor slot harmonics mathematically, it is first determined whether or not the rotor slot harmonics are present in the motor current spectrum for the induction motor. All induction motors do not exhibit rotor slot harmonic components in their corresponding motor current spectrum. Determining that rotor slot harmonics are present in the motor current spectrum for the induction motor includes determining that an equation:

$${N}_{R} = 2 {p}_{p} ( 3 α + κ ) \qquad ( 1 )$$

is satisfied, wherein N_{R} is a number of rotor bars, pₚ is a number of pole pairs, α=1, 2, 3, . . . , and κ=−1, 0, 1.

The motor current spectrum is associated with the rotor bar number of the motor. The RSH component in the motor current spectrum is provided as:

$$freq = ( ( k R \pm {n}_{d} ) \frac{( 1 - s )}{{p}_{p}} \pm v ) \times f . \qquad ( 2 )$$

wherein n_{d} is the dynamic eccentricity, R is the number of rotor slots, pₚ is the number of pole pairs, k is a constant, v is the harmonics 1, 3, 5, . . . , f is the supply frequency, and s is motor slip. For a particular loading condition N₁, operating the induction motor with current i_{L1}, to produce rotational speed N₁, it can be seen that the rotor slot harmonics in the motor current spectrum are correlated with the speed of the motor. In an induction motor, the rotor speed rotates at a speed less than the rotating magnetic field of the stator, e.g., the rotational speed. For example, using equation (2) with n_{d}=0, v=1, and K=1, the slot harmonic frequency can be estimated by:

$$freq 1 = ( ( R ) \frac{{N}_{1}}{{p}_{p} \times {N}_{s}} \pm 1 ) \times f . \qquad ( 3 )$$

$$freq {1}_{a} = ( ( R ) \frac{{N}_{1}}{{p}_{p} \times {N}_{s}} + 1 ) \times f$$

$$freq {1}_{b} = ( ( R ) \frac{{N}_{1}}{{p}_{p} \times {N}_{s}} - 1 ) \times f$$

$$Δ f = f req {1}_{a} - f req {1}_{b} = 2 \times f . \qquad ( 4 )$$

Equation (4) illustrates that the sidebands for a given load e.g., N₁, has a frequency difference of 2f. It can be concluded from equations (3) and (4) that for a given supply frequency f, as the load of the motor increases, the RSH change and are therefore load dependent.

The frequency difference between peaks on the motor current spectrum due to different loading conditions N₁ and N₂ can be calculated as:

$$freq {1}_{al 1} - freq {1}_{al 2} = ( ( R ) \frac{{N}_{1}}{{p}_{p} \times {N}_{s}} + 1 ) \times f - ( ( R ) \frac{{N}_{2}}{{p}_{p} \times {N}_{s}} + 1 ) \times f = \frac{R \times ( {N}_{1} - {N}_{2} ) \times f}{{p}_{p} \times N s} = \frac{R \times ( {N}_{1} - {N}_{2} )}{60} . \qquad ( 5 )$$

Based on the above conclusion that the rotor slot harmonics of the frequency are speed dependent, a simplified method is presented in which the only input necessary to perform the method is current data obtained by operating the induction motor at two different load conditions (e.g., rotational speeds).

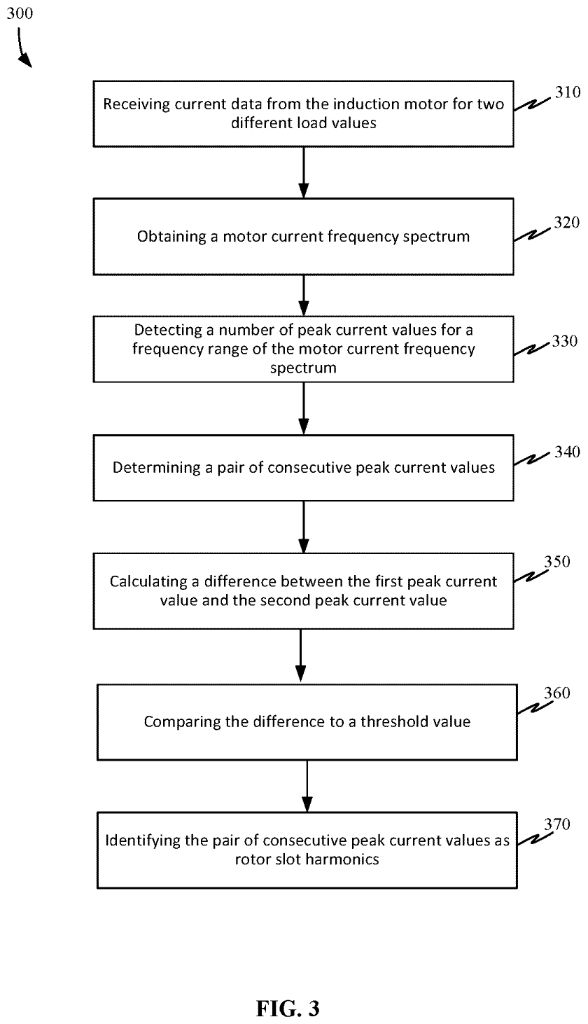

FIG. 3 illustrates a flowchart of a method to identify rotor slot harmonics in a motor current spectrum of an induction motor. Referring to FIG. 3, method 300 begins upon receiving (310) current data from the induction motor for two different load values. The induction motor is operated with two different loading conditions, e.g., currents, i_{L1} and i_{L2} to produce corresponding speeds N₁ and N₂, in which the current data is captured for the two different load values. A code of method 300 can be integrated into the control and monitoring unit 150, 250.

Method 300 further includes obtaining (320) a motor current frequency spectrum comprising a first motor current spectrum corresponding to a first load value and a second motor current spectrum corresponding to a second load value. The motor current frequency spectrum can be obtained by performing a FFT, or other frequency-domain signal processing technique, on the received current data from the induction motor for the two different load values to produce the first motor current spectrum corresponding to the first load value and the second motor current spectrum corresponding to the second load value.

Method 300 further includes detecting (330) a number of peak current values for a frequency range of the motor current frequency spectrum. Detecting the number of peak current values for a frequency range of the motor current frequency spectrum can include calculating a mean value from a plurality of current values within the frequency range and comparing each current value of the plurality of current values to the mean value. When the comparison of the current value is above a threshold value, a peak current value is detected.

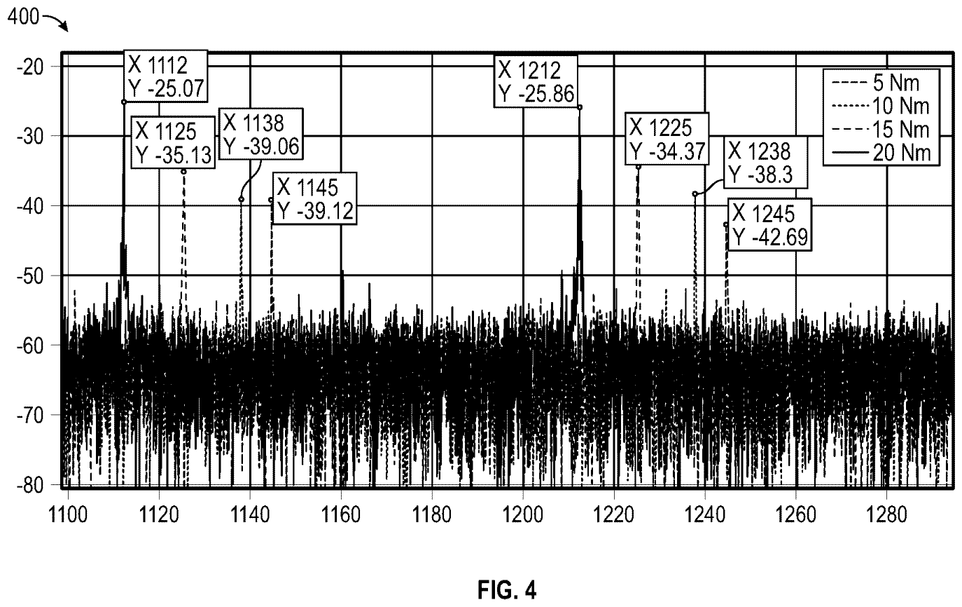

For example, FIG. 4 illustrates a graph of a motor current frequency spectrum of a 10 HP induction motor operated with a DOL soft starter. Referring to FIG. 4, graph 400 illustrates a multitude of different current values displayed for the frequency range on the illustrated graph for four different loading conditions. In order to filter out the meaningful values, e.g., the current peak values, from the current values on the motor current frequency spectrum for a particular frequency range on the graph, a mean value of all the values can be calculated. The values close to the mean value, e.g., below a threshold value, can be removed while only the values above the threshold value are considered as peak current values. The peak current values are easily seen on the graph of FIG. 4 as they rise above the other values close to a mean value (and are marked with x, y values on the graph).

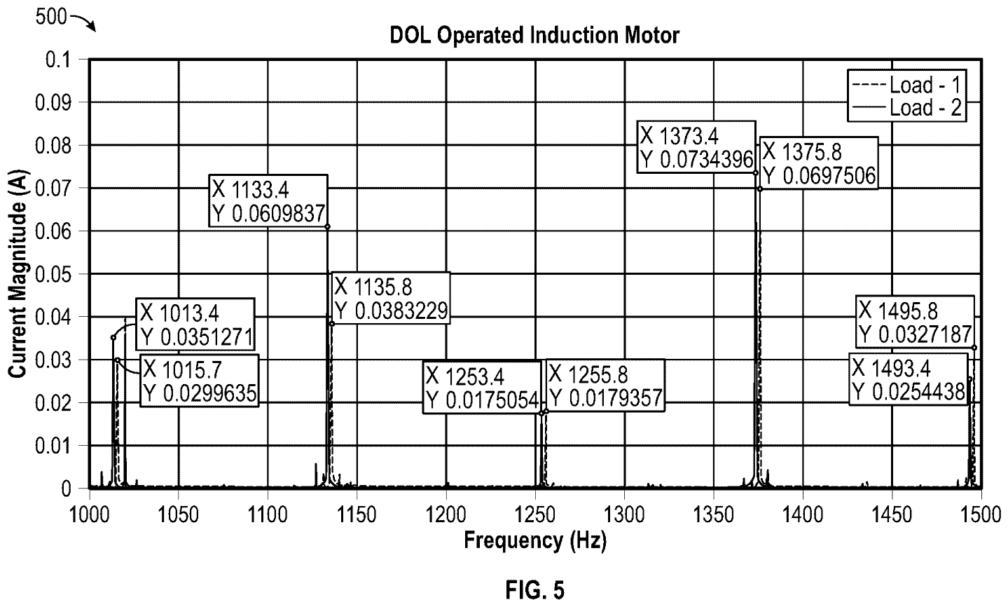

FIG. 5 illustrates a motor current spectrum of 40 HP induction motor operated by a DOL soft starter. Referring to FIG. 5, graph 500 shows a result of detecting the number of current peaks for the frequency range by removing unmeaningful current values e.g., noise. As can be seen in graph 500, pairs of consecutive peak current values are shown.

The pairs of consecutive peak current values can then be compared to determine whether the current peak values are rotor slot harmonics. Method 300 further includes determining (340) a pair of consecutive peak current values. The pairs of consecutive peak current values lie adjacent to one another on the graph, e.g., at frequency values that are close to one another. Each pair of consecutive current peak values includes a first current peak value from the first motor current spectrum corresponding to a first load value and a second current peak value from the second motor current spectrum corresponding to a second load value.

Method 300 further includes calculating (350) a difference between the first current peak value and the second current peak value. The difference can then be compared (360) to a threshold value. The threshold value can be dependent on the number of rotor poles. In some cases, the threshold can be in a range between 1-20 Hz. When the peak current values are greater than zero and less than a threshold value, the peak current values are identified (370) as rotor slot harmonics.

In some cases, once the peak current values have been identified as rotor slot harmonics, a verification computation can be performed. The verification computation can include determining a difference between two consecutive peak current values for the same load value. The two consecutive peak current values for the same load value include the first peak current value for the first load value and a third peak current value for the first load value or the second peak current value for the second load and a fourth peak current value for the second load. When the difference between the consecutive peak current values is two times a supply frequency, it is verified that the identified current peaks are rotor slot harmonics. For example, referring to FIG. 5, it can be seen from the that for load 2, there is one peak current value at 1253.4 and a consecutive peak current value at 1373.4. A difference between these two peak current values is 120 Hz which is 2 times the supply frequency of 60 Hz.

In some cases, the identified rotor slot harmonics can be stored on a computer readable storage medium. The stored identified rotor slot harmonics can be used at a later time to estimate the speed of the induction motor or diagnose faults of the motor. In some cases, the stored RSH can be used as a baseline measurement to be used in calculations/estimations of variables indicating an induction motor operating normally. In some cases, the identified RSH components can later be used to determine the remaining useful life (RUL) of the induction motor, for example. In some cases, the stored RSH can be used to estimate a baseline rotor speed, N_{rb}. Measuring a difference in a rotor speed from the baseline rotor speed N_{rb} can also determine an anomaly of the induction motor. For example, a change in the value of the identified RSH frequency component indicates a change in the speed of the induction motor. This change in the RSH frequency components with respect to the induction motor operating under the same conditions can indicate an anomaly in the induction motor. The higher the difference of the RSH frequency components from the baseline measurement can correlate to a higher fault severity.

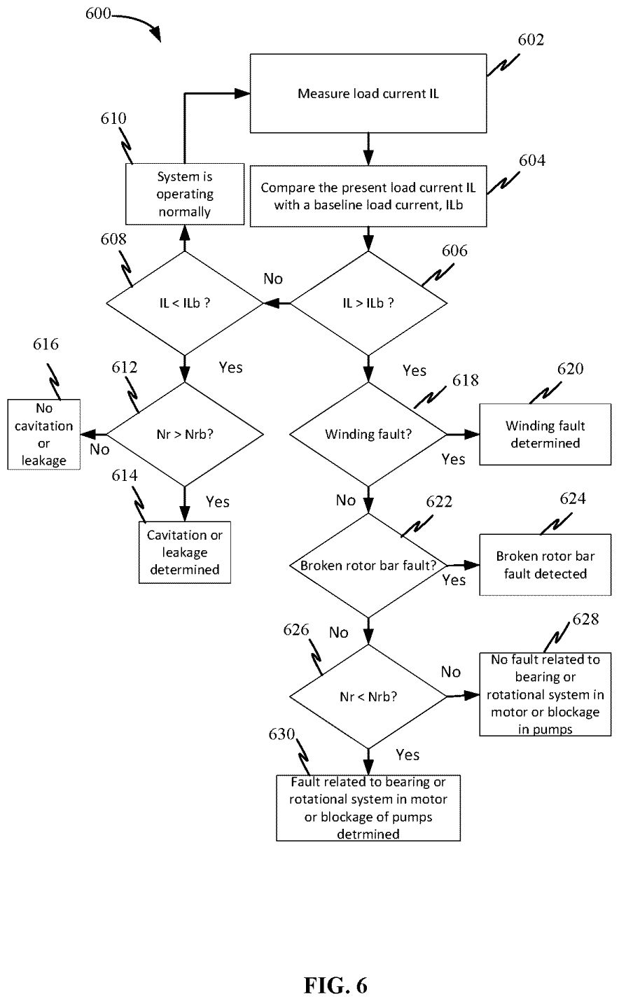

The identified rotor slot harmonics can be used to estimate the rotor speed according to known methods. The estimated rotor speed can then be used to determine a fault in the induction motor or in an induction motor driven system. For example, an induction motor can be used to drive a load, such as a pump or a compressor, creating the induction motor driven system. FIG. 6 illustrates a flowchart depicting a method to determine induction motor system faults using identified RSH. For example, the rotor slot harmonic components can be used for determination of a winding fault, a broken rotor bar fault, a cavitation fault, a bearing fault, rotational fault, and a pump blockage fault.

Referring to FIG. 6, method 600 begins by measuring (602) a current of the load, I_{L}. A baseline load current, I_{Lb} and a baseline rotor speed, N_{rb}, of the induction motor operated with the same load under the same supply frequency and operating conditions are used in the process. These values can be previously determined and stored in memory. The baseline rotor speed N_{rb} can be estimated using identified rotor slot harmonics from the measured baseline load current determined according to method 300. The rotor speed Nᵣ is estimated using traditional methods from its frequency information obtained from the motor current spectrum, e.g., by using equation (2). Slip, s, can be back calculated from frequency, f. Nr is then calculated using the slip, s, and synchronous speed Nₛ. The measured load current I_{L} is first compared (604) to the baseline load current I_{Lb}. Additionally, the baseline load speed, N_{rb}, is then compared (second comparison) to the estimated rotor speed Nᵣ. A fault of the induction motor or induction motor system can be determined from these two comparisons.

In some cases, a cavitation or leakage fault of the driven load can be determined. Cavitation in a pump is a condition where the liquid being pumped forms and collapses vapor bubbles due to low pressure. Cavitation and water leakage can be determined in all types of pumps (e.g., centrifugal pump, displacement pump, etc.) Air leakage can be determined in all types of compressors. At the same supply frequency and operating conditions, when the measured load current I_{L} is less than the baseline load current I_{Lb} (608) and the rotor speed Nᵣ is greater than the baseline load speed N_{rb} (612), a cavitation/leakage fault can be determined (614). If the load current I_{L} is equal to the baseline load current I_{Lb}, the system is operating normally (610). If the rotor speed Nᵣ is not greater than the baseline rotor speed N_{rb}, a cavitation/load fault is not determined (616).

In some cases, at the same supply frequency and operating conditions, the load current I_{L} being greater than the baseline load current I_{Lb} (606) can indicate a winding fault (618) or a broken rotor bar fault (622). After the first comparison indicates a fault (606), a winding fault or a broken rotor bar fault can be determined (620, 624) by a technician using existing methods.

After verifying that there is not a winding fault or a broken rotor bar fault, a pump blockage or rotational system fault can be determined. At the same supply frequency and operating conditions, when the load current I_{L} is greater than the baseline load current I_{Lb} (606) and the rotor speed Nᵣ is less than the baseline rotor speed N_{rb} (626), a rotational/pump blockage fault can be determined (628). Rotational faults can include issues with a bearing such as a roughness issue or too much wear to the bearing. If the rotor speed Nᵣ is greater than the baseline rotor speed, it can be determined (630) that there is no fault related to a bearing or rotational system in motor or blockage of a pump.

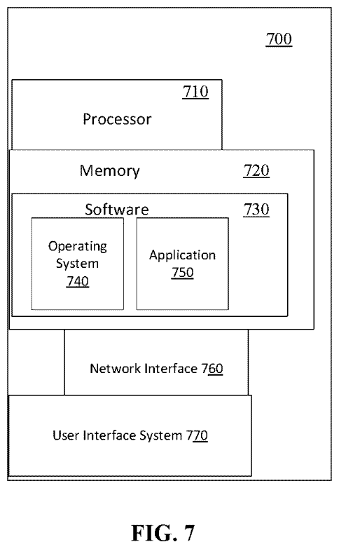

FIG. 7 illustrates a schematic diagram illustrating components of a computing device that may be used in certain implementations described herein. The computing device can be representative of the control and monitoring unit as described herein. Referring to FIG. 7, computing device 700 can represent a personal computer, a reader, a mobile device, a personal digital assistant, a wearable computer, a smart phone, a tablet, a laptop computer, a gaming device, or console, an entertainment device, a hybrid computer, a desktop computer, or a smart television. Accordingly, more or fewer elements described with respect to computing device 700 may be incorporated to implement a particular computing device.

The computing device 700 can include at least one processor 710, a memory 720, software 730 that includes operating system 740 and application 750, network interface 760, and user interface 770. Processor 710 processes data according to instructions of software 730. The instructions of application 750 may be loaded into computing device 700 and run on or in association with the operating system 740. Application 750 can include the methods as described. Memory 720 may comprise any computer readable storage media readable by processor 710 and capable of storing software including application 750.

Computing device 700 can further include a user interface 770, which may include input/output (I/O) devices and components that enable communication between a user and the computing device 700. Computing device 700 may also include a network interface 660 that allows the system to communicate with other computing devices, including server computing devices and other client devices, over a network.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts that would be recognized by one skilled in the art are intended to be within the scope of the claims.

What is claimed is:

1. A computer-implemented method to identify rotor slot harmonics in a motor current spectrum of an AC induction motor, comprising:
receiving current data from the AC induction motor operated at two different load values;
obtaining a motor current frequency spectrum comprising a first motor current spectrum corresponding to a first load value and a second motor current spectrum corresponding to a second load value;
detecting a number of peak current values for a frequency range of the motor current frequency spectrum; and
comparing the detected number of peak current values for the frequency range from the first motor current spectrum to the second motor current spectrum by:
determining a pair of consecutive peak current values from the detected number of peak current values, the pair of consecutive peak current values include a first peak current value for the first load value and a second peak current value for the second load value;
calculating a difference between the first peak current value and the second peak current value;
comparing the difference to a threshold value; and
in response to the difference being greater than zero and less than the threshold value, identifying the pair of consecutive peak current values as rotor slot harmonics.

2. The method of claim 1, further comprising estimating a speed of the motor using identified rotor slot harmonics.

3. The method of claim 2, further comprising diagnosing a fault using identified rotor slot harmonics.

4. The method of claim 1, wherein the first load value is a first current, i_{L1}, and the second load value is a second current, i_{L2}.

5. The method of claim 1, further comprising determining that rotor slot harmonics are present in the motor current frequency spectrum for the AC induction motor prior to obtaining the motor current frequency spectrum.

6. The method of claim 5, wherein determining that rotor slot harmonics are present in the motor current spectrum for the induction motor includes determining that an equation N_{R}=2pₚ(3α+κ) is satisfied, wherein N_{R} is a number of rotor bars, pₚ is a number of pole pairs, α=1, 2, 3, . . . , and κ=−1, 0, 1.

7. The method of claim 1, wherein obtaining a current frequency spectrum for the two different load values includes performing a FFT on the received current data from the induction motor operated at the two different load values to produce the first motor current spectrum corresponding to the first load value and the second motor current spectrum corresponding to the second load value.

8. The method of claim 1, wherein detecting the number of peak current values for a frequency range of the motor current frequency spectrum includes:
calculating a mean value from a plurality of current values within the frequency range;
comparing each current value of the plurality of current values to the mean value; and
in response to the comparison of the current value being above a threshold value, detecting the current value as a peak current value.

9. The method of claim 1, further comprising storing the identified rotor slot harmonics as a baseline measurement in a memory of a computer readable storage medium.

10. The method of claim 1, further comprising verifying identified peak current values are rotor slot harmonics by determining a difference between two consecutive peak current values from a same load value, wherein the two consecutive peak current values for the same load value include the first peak current value for the first load value and a third peak current value for the first load value or the second peak current value for the second load and a fourth peak current value for the second load and in response to the difference between the consecutive peak current values being two times a supply frequency, verifying that the identified current peaks are rotor slot harmonics.

11. The method of claim 1, wherein the threshold is in a range of 1-20 Hz.

12. The method of claim 1, wherein a motor drive of the AC induction motor is coupled to one of a variable frequency drive and a DOL soft starter.

13. A method to determine a fault of an induction motor system, comprising:
driving a load by an induction motor;
measuring a current of the load driven by the induction motor;
estimating a rotor speed of the induction motor;
performing a first comparison by comparing the measured current of the load to a baseline load current;
performing a second comparison by comparing the estimated rotor speed of the induction motor to a baseline rotor speed wherein the baseline rotor speed is estimated using identified rotor slot harmonics; and
determining a fault of the induction motor system based on the first comparison and the second comparison.

14. The method of claim 13, wherein the rotor slot harmonics are identified by:
receiving current data from an induction motor operated at two different load values;
obtaining a motor current frequency spectrum comprising a first motor current spectrum corresponding to a first load value and a second motor current spectrum corresponding to a second load value;
detecting a number of peak current values for a frequency range of the motor current frequency spectrum; and
comparing the detected number of peak current values for the frequency range from the first motor current spectrum to the second motor current spectrum by:
determining a pair of consecutive peak current values from the detected number of peak current values, the pair of consecutive peak current values include a first peak current value for the first load value and a second peak current value for the second load value;
calculating a difference between the first peak current value and the second peak current value;
comparing the difference to a threshold value; and
in response to the difference being greater than zero and less than the threshold value, identifying the pair of consecutive peak current values as rotor slot harmonics.

15. The method of claim 13, wherein determining a fault of the induction motor system includes: in response to the measured current of the load being less than the baseline load current from the first comparison and the estimated rotor speed of the induction motor being greater than the baseline rotor speed from the second comparison, determining a cavitation/leakage fault.

16. The method of claim 13, wherein determining a fault of the induction motor includes: in response to the measured current of the load being greater than the baseline load current from the first comparison and the estimated rotor speed of the induction motor being less than the baseline rotor speed from the second comparison, determining a rotational/blockage fault.

17. The method of claim 13, wherein determining a fault of the induction motor system includes: in response to the measured current of the load being greater than the baseline load current from the first comparison, performing a winding fault test to determine a winding fault.

18. The method of claim 13, wherein determining a fault of the induction motor system includes: in response to the measured current of the load being greater than the baseline load current from the first comparison, performing a broken rotor bar fault test to determine a broken rotor bar fault.
